(19) United States
(12) Patent Application Publication
(10) Pub. No.: US 2026/0282805 A1
(43) Pub. Date: Sep. 17, 2026

(54) HEATER PLATE WITH DIFFERENT EMISSIVITY FOR TEMPERATURE UNIFORMITY

(71) Applicant: ASM IP Holding B.V., Almere (NL)

(72) Inventors: Masaei Suwada, Nagaoka-shi (JP); Taira Okabe, Kawasaki-shi (JP); Masashi Nakano, Tokyo (JP)

(21) Appl. No.: 19/563,079

(22) Filed: Mar. 11, 2026

Related U.S. Application Data
(60) Provisional application No. 63/772,299, filed on Mar. 14, 2025.

(51) Int. Cl. H10P 72/00; B25J 11/00; F27B 17/00; F27D 99/00; F28F 13/18

(52) U.S. Cl. CPC H10P 72/0436; B25J 11/0095; F27B 17/0025; F27D 99/0006; F28F 13/185; H10P 72/0454; H10P 72/0466; F27D 2099/0011; F28F 2245/06

(57) ABSTRACT

A semiconductor device processing system having a heater plate with different emissivities is described. A process for varying the emissivity of the heater plate is also described. In some examples, the emissivity of the heater plate may be varied by modifying the surface roughness of selected regions of the heater plate. The surface roughness of the selected regions may be modified by various techniques including, for instance, blasting, abrading, plating, painting, and/or anodizing. The heater plate may be part of a cluster-type semiconductor processing platform, located in a load lock, and/or located in individual process modules. One example of the method for modifying the surface roughness includes modeling and adjusting the surface roughness. Another example of the method includes testing and modifying the surface roughness.

### CROSS-REFERENCE TO RELATED APPLICATIONS

This application claims priority to U.S. Provisional Patent Application Ser. No. 63/772,299 filed Mar. 14, 2025 and titled HEATER PLATE WITH DIFFERENT EMISSIVITY FOR TEMPERATURE UNIFORMITY, the disclosure of which is hereby incorporated by reference in its entirety.

### TECHNICAL FIELD

The present disclosure relates generally to the field of semiconductor processing methods and systems and to the field of device and integrated circuit manufacture. More particularly the present disclosure generally relates to adjusting the emissivity of regions of a heater plate to reduce temperature variation across a heated wafer.

### BACKGROUND

Semiconductor processing requires semiconductor wafers to be at proper temperatures for desired reactions to occur. For example, some processes require higher temperatures while other processes require lower temperatures. Once a semiconductor wafer has been positioned in a process chamber, the temperature in the process chamber is adjusted to a desired process temperature. To reduce the time required to heat a wafer from room temperature (e.g., 22° C.) to a process temperature (e.g., 150-650° C.), the wafer may be pre-heated on a heater plate while waiting for the process chamber to finish processing another wafer. The location of the heater plate relative to other components in the processing system and the physical geometries of the heating elements in the heater plate may result in temperature variations across the wafer. While clearances may be minimized to reduce the effect of cooling air flows at the ends of a heating system heating the wafer, differences between the ambient temperature and the temperature of the heated wafer may cause some regions of the wafer to be cooler than other regions. Those variances require additional heating time to minimize the differences, either at the heating system or downstream in subsequent heating systems or process modules.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to reducing temperature variations across a wafer by modifying the emissivity of regions of a heater plate. A heater plate with regions of different emissivities allows for more or less heating to be applied to the wafer. In some examples, the heater plate may comprise two regions having different emissivities. In other examples, the heater plate may comprise three or more regions having different emissivities. In yet further examples, the emissivity variations may be represented by a gradient across one or more portions of the heater plate.

As described herein, the emissivity of a region of the heater plate may be varied by modifying the surface roughness of the region. The surface roughness may be modified by various processes including blasting, abrading, plating, painting, and/or anodizing one or more regions of the heater plate. Processes are described for adjusting the surface roughness of heater plates.

In addition to one or more of the features described above, or as an alternative, methods in accordance with at least some examples of this technology may use semiconductor or other substrate processing systems having any of the features and/or combinations of features described above.

In accordance with examples of the disclosure, a load-lock module comprises a first gate valve connectable to an equipment front-end module; a second gate valve connectable to a substrate handling chamber; and a heater plate. The heater plate comprises a surface having a center region with a center region emissivity and a peripheral region with a peripheral region emissivity and heating elements in a body of the heater plate. In the first example, the peripheral region emissivity is greater than the center region emissivity. In one example, a roughness of the peripheral region is greater than a roughness of the center region. In another example, the peripheral region is darker in color than the center region. In yet another example, a transition between the peripheral region and the center region is defined by a large decrease in emissivity. Alternatively, the transition between the peripheral region and the center region is a gradient in roughness. In a further example, the surface may include a third region between the center region and the peripheral region. An emissivity of the third region may be less than the peripheral region emissivity. The emissivity of the third region may be greater than the center region emissivity. The peripheral region emissivity may have been increased by blasting, abrading, plating, painting, or anodizing.

In accordance with examples of the disclosure, a cluster platform comprises a plurality of process modules and a load-lock module. The load-lock module comprises a first gate valve connectable to an equipment front-end module; a second gate valve connectable to a substrate handling chamber; and a heater plate. The heater plate comprises a surface having a center region with a center region emissivity and a peripheral region with a peripheral region emissivity, and heating elements in a body of the heater plate. The peripheral region emissivity is greater than the center region emissivity. The second embodiment further comprises a substrate handling chamber including a first robotic arm configured to move wafers between the process modules and the load-lock module. The cluster platform may include a front-end module comprising a second robotic arm configured to move wafers between the load-lock module and one or more loading ports. A roughness of the peripheral region may be greater than a roughness of the center region. The peripheral region may be darker in color than the center region. The transition between the peripheral region and the center region may be defined by a large decrease in emissivity. Alternatively, the transition between the peripheral region and the center region may be a gradient in roughness. The surface may further comprise a third region between the center region and the peripheral region. The surface may include a third region between the center region and the peripheral region. An emissivity of the third region may be less than the peripheral region emissivity. The emissivity of the third region may be greater than the center region emissivity. The peripheral region emissivity may have been increased by blasting, abrading, plating, painting, or anodizing.

In accordance with examples of the disclosure, a process module comprises process equipment configured to perform a semiconductor-related process at an elevated temperature and a heater plate. The heater plate comprises a surface having a center region with a center region emissivity and a peripheral region with a peripheral region emissivity and heating elements in a body of the heater plate. The peripheral region emissivity is greater than the center region emissivity. In further examples, roughness of the peripheral region may be greater than a roughness of the center region. The peripheral region may be darker in color than the center region. A transition between the peripheral region and the center region may be defined by a large decrease in emissivity. Alternatively, the transition between the peripheral region and the center region is a gradient in roughness. Further, the surface of the heater plate of the process module may include a third region between the center region and the peripheral region. The third region may have an emissivity less than the peripheral region emissivity and greater than the center region emissivity.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates an example of temperature variation across a surface of a heater plate in accordance with one or more embodiments of the disclosure.

FIG. 2A illustrates locations of heating elements in a heater plate. FIG. 2B illustrates an estimated variation in temperatures across the surface of a heater plate. FIG. 2C illustrates an estimated variation in temperatures across the surface of a wafer.

FIG. 3A illustrates an elevation view of an example of a heater plate with modified emissivities of the heater plate. FIG. 3B illustrates a plan view of the heater plate with the modified emissivities.

FIG. 4A illustrates a plan view of an alternate heater plate with modified emissivities.

FIG. 4B illustrates a plan view of another alternate heater plate with modified emissivities in accordance with one or more embodiments of the disclosure.

FIG. 5 illustrates an elevation view of a load-lock module in accordance with one or more embodiments of the disclosure.

FIG. 6 illustrates an illustrative diagram of temperature transfer for a wafer and temperature-adjusting plate.

FIG. 7A illustrates a graph of heat conduction by radiation, conduction, and convection.

FIGS. 7B and 7C illustrate heat conduction for molecular flow and viscous flow in accordance with one or more embodiments of the disclosure.

FIG. 8 illustrates an elevation view of a heater plate having variations in surface roughness in accordance with one or more embodiments of the disclosure.

FIG. 9 illustrates a system with process modules, a load lock, and one or more heater plates in accordance with one or more embodiments of the disclosure.

FIG. 10 illustrates a process for modifying the emissivity of one or more regions of a heater plate in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. The substrate can include various topologies, such as gaps, including recesses, lines, trenches or spaces between elevated portions, such as fins, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

As used herein, the term “layer” can refer to any continuous or non-continuous structure and material. For example, a layer can include two-dimensional materials, three-dimensional materials, nanoparticles or even partial or full molecular layers or partial or full atomic layers or clusters of atoms and/or molecules. A layer may comprise material or a layer with pinholes, which may be at least partially continuous.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

As used herein, the term structure can include a substrate and a layer. A structure can form part of a device, such as a device as described herein. Structures can undergo further processing steps (such as deposition, etching, cleaning, and the like) to form a device.

In the following description of the various embodiments, reference is made to the accompanying drawings, which form a part hereof, and which are shown by way of illustration of various embodiments in which aspects of the disclosure may be practiced. It is to be understood that other embodiments may be utilized and structural and functional modifications may be made without departing from the scope of the present disclosure. Any sequence of computer-implementable instructions described in this disclosure may be considered to be an “algorithm” as those instructions are intended to solve one or more classes of problems or to perform one or more computations. While various directional arrows are shown in the figures of this disclosure, the directional arrows are not intended to be limiting to the extent that bi-directional communications are excluded. Rather, the directional arrows are to show a general flow of steps and not the unidirectional movement of information. Throughout the specification, the expressions “at least one of a, b, and c” and “one or more of a, b, and c” may include ‘a only’, ‘b only’, ‘c only’, ‘a and b’, ‘a and c’, ‘b and c’, and/or ‘all of a, b, and c’.

It is noted that various connections between elements are discussed in the following description. It is noted that these connections are general and, unless specified otherwise, may be direct or indirect, and that the specification is not intended to be limiting in this respect. As described herein, thresholds are referred to as being “satisfied” to generally encompass situations involving thresholds above increasing values as well as encompass situations involving thresholds below decreasing values. The term “satisfied” is used with thresholds to address when values have passed a threshold and then approaching the threshold from an opposite side using terms such as “greater than”, “greater than or equal to”, “less than”, and “less than or equal to” can add ambiguity where a value repeatedly crosses a threshold.

Certain aspects relate to improving the ability of a heater plate to heat a semiconductor substrate while minimizing the variation of temperature across the heated wafer. In some aspects, the improvements may pertain to improving the evenness of temperatures across various regions of a wafer. In other aspects, the improvements may pertain to a process for modifying the emissivities of a heater plate to account for individual temperature variations for a particular heater plate. In further aspects, the improvements may pertain to improving how temperature, in a reaction chamber, is controlled. In yet further aspects, the improvements may pertain to increasing the throughput of a reactor system having multiple reactor modules.

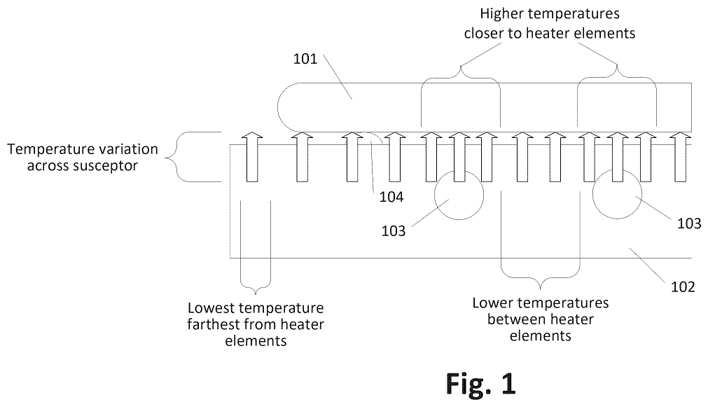

Turning now to the figures, FIG. 1 shows an example of temperature variation across a surface of a heater plate. A wafer 101 is shown on a heater plate 102. The heater plate 102 may be located in a load-lock module, in a wafer-handling chamber, or a process module. The heater plate 102 includes heating elements 103 (e.g., resistive heating coils) positioned to heat the wafer 101. The wafer 101 is close to but spaced from the surface of the heater plate 102 by one or more spacers 104. To reduce temperature variations across the wafer 101 due to air currents, the spacers 104 do not raise the wafer significantly from the heater plate 102.

The heat from the heating elements 103 is shown by the up arrows in FIG. 1. The spacings between the heating elements 103 affect the consistency of heat provided across the surface area of the heater plate. In FIG. 1, the variation is shown by a greater concentration of arrows above the heating elements 103 and a lesser concentration between the heating elements 103. Further, at a periphery of the heater plate 102, the heating elements 103 may not be able to effectively maintain a consistent heat compared to the heat provided nearer the center of the heater plate 102. The reduced ability to provide a constant heat flux close to the periphery of the heater plate 102 is shown by the greater spacing between the up arrows near the left side of the heater plate 102 of FIG. 1.

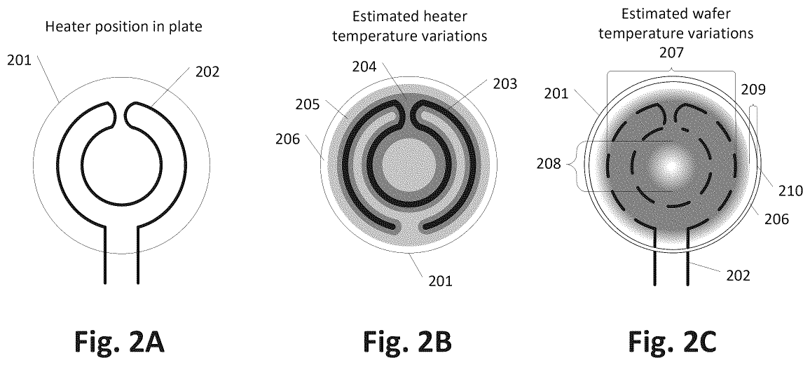

FIGS. 2A-2C show estimates of how temperature variations across a heater plate may affect the heating of a wafer. FIG. 2A shows the locations of heating elements 202 in a heater plate 201. The arrangement of heating elements 202 may take any shape.

FIG. 2B shows an estimated variation in temperatures across the surface of a heater plate 201. The heating elements of FIG. 2A are not shown in FIG. 2B but the variation in the heat provided across the surface of the heater plate 201 are shown. The variations are shown by the hottest regions 203, slightly cooler regions 204 next to the hottest regions 203, cooler regions 205 surrounding the slightly cooler regions 204, and the regions 206, at the periphery of the heater plate 201, having the lowest temperature. For purposes of illustration, regions 203, 204, 205, and 206 are shown as distinct regions. One would appreciate that distinct boundaries are not present between the regions but reflect gradual changes across the regions.

FIG. 2C shows an estimated variation in temperatures across the surface of a wafer. A wafer 210 has relatively consistent heating across region 207 but with a slight drop in the center, as shown by region 208. The coolest region 209 is near the periphery of wafer 210 due to the smallest heat flux of the heater plate 201 in region 206. For reference, heater plate 201 and heating elements 202 are shown for reference. Heating elements 202 under the wafer 210 are shown in dashed lines.

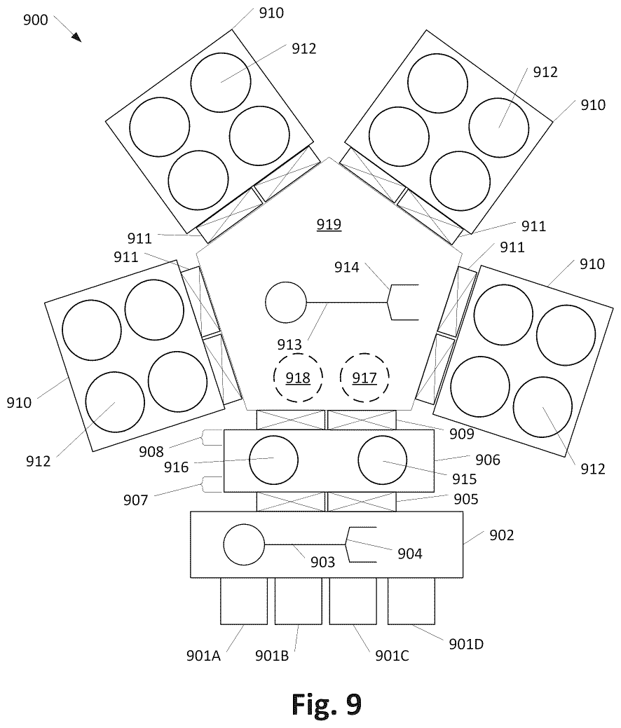

Temperature variations across a surface of a wafer may be measured. For instance, the temperature of multiple regions may be measured. The temperatures for corresponding regions across a wafer are not always consistent. The inconsistency may be due to the variations in heating elements in the heater plate. The inconsistency may be due to the proximity of a given region to another component that is at a different temperature. For instance, the heater plate may be in a load-lock module of a semiconductor cluster platform. One end of the wafer may be closer to a wafer handling component (hereinafter, “WHC”) further inside the semiconductor cluster platform. An example of the WHC is the substrate handling chamber 919 of FIG. 9 described below. Another example of the WHC is generally one or more semiconductor processing modules and one or more structures (e.g. robotic arms, conveyor belts, etc.) to move the wafers from the heater plate. As described herein, the heater plate may be in a load-lock module, in a substrate handling chamber, and/or in a process module. In this regard, the scope of the WHC changes based on where the heater plate is located. For instance, if the heater plate is in a load-lock module, the WHC includes include the substrate handling chamber and one or more process modules. If the heater plate is in the substrate handling chamber, the WHC includes one or more process modules. If the heater plate is in a process module, the WHC includes the equipment and/or location of where a wafer is subsequently processed in the process module. Another side of the wafer may be closer to a lower temperature, equipment front-end module (hereinafter, “EFEM”) into which wafers are received from and returned to a front opening unified pod (also known as front opening universal pod) (hereinafter, “FOUP”). The EFEM may be operating at a lower temperature while the WHC is operating at a higher temperature. Those temperature variations may appear as differing temperatures across the wafer where the wafer handling component is at a higher temperature than the EFEM.

The heater plates of FIGS. 1, 2A, 2B, and 2C are generally represented as having upper surfaces with emissivities. Despite the constant emissivities, other factors contribute to the wafers being unevenly heated by the heater plates. The uneven heating of the wafers requires the wafers to be reheated to minimize the variation in temperatures across the heated wafers. That reheating process consumes valuable processing time. By reducing the variation in temperatures across a heated wafer, the extra processing time required to reheat the wafer may be reduced.

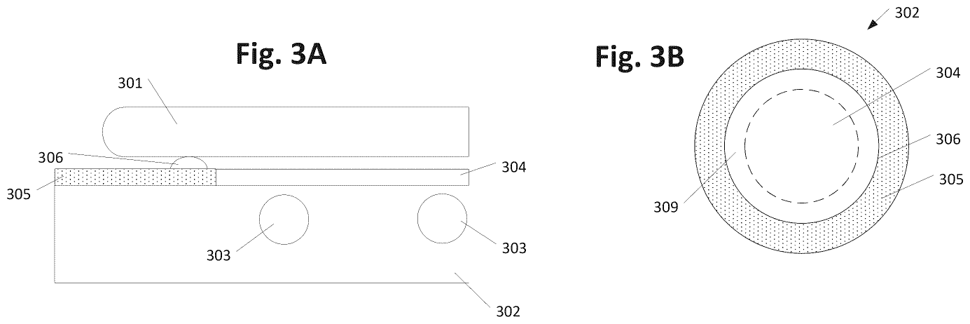

FIG. 3A shows an elevation view of an example of a heater plate with modified emissivities of the heater plate. FIG. 3A shows a wafer 301 positioned above a heater plate 302 and supported by one or more spacers 306. Heating elements 303 are shown within the body of heater plate 302. The upper surface of the heater plate 302 is shown with two regions. A first region 304 is closer to the center of the heater plate 302. A second region 305 of the upper surface of the heater plate 302 is located between the first region 304 and the outer periphery of the heater plate 302. The emissivity of region 304 is lower than the emissivity of region 305. The higher the emissivity, the greater the heat transfer through a respective region.

FIG. 3B shows a plan view of the heater plate 302 with the regions having different emissivities. The first region 304 is shown at the center of the upper surface of heater plate 302. The second region 305 is shown as a ring around the first region 304. For purposes of illustration, FIG. 3B shows a clear distinction 306 between region 304 having the lower emissivity and region 305 having the higher emissivity. Other regions having other emissivities may also be present (e.g., three distinct regions, four or more distinct regions, etc.). In other examples, there may be no clear distinction between the regions having different emissivities. In a further example, a third region 309 (shown in dashed lines as part of the first region 304) may be included that has a different emissivity from the emissivities of the first region 304 and the second 305.

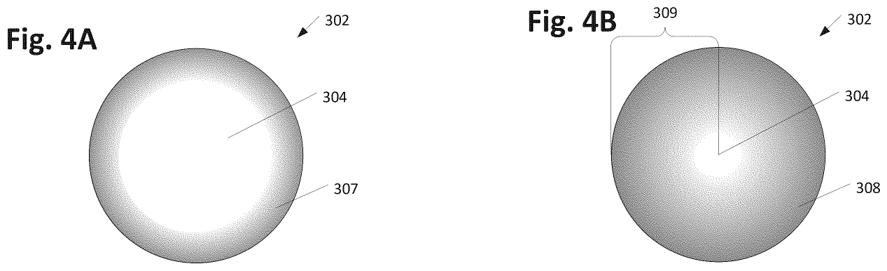

FIG. 4A shows a plan view of an alternate heater plate with modified emissivities. FIG. 4A shows heater plate 302 with a center region 304 having a lower emissivity and an outer region 307 having a higher emissivity. In contrast to the abrupt change in emissivity of the regions of FIGS. 3A and 3B, FIG. 4A shows a gradient in emissivity across region 307 with little to no change in emissivity across region 304.

FIG. 4B shows a plan view of another alternate heater plate with modified emissivities. FIG. 4B shows heater plate 302 with a center region 304 having a lower emissivity and an outer region 308 having a higher emissivity. In contrast to the abrupt change in emissivity of the regions of FIGS. 3A and 3B and in contrast, the change in emissivity being localized to region 307 of FIG. 4A, FIG. 4B shows a gradient in emissivity across most (if not all) of the surface of heater plate 302. Region 308 is shown with the highest emissivity and region 304 is shown with the lowest emissivity. The change in emissivity across radial direction 309 may be constant or have any other profile as desired.

An estimated result is the inner regions of the wafer do not change in temperature while the outer regions of the wafer do increase in temperature. For the purposes of explanation, the temperatures are estimated to be reduced by half their difference from the desired temperature of 193° C. Other estimates are relevant as well based on how the temperatures of the wafer's regions overlying the heater's regions with higher emissivities are expected to change with the modified heater plate.

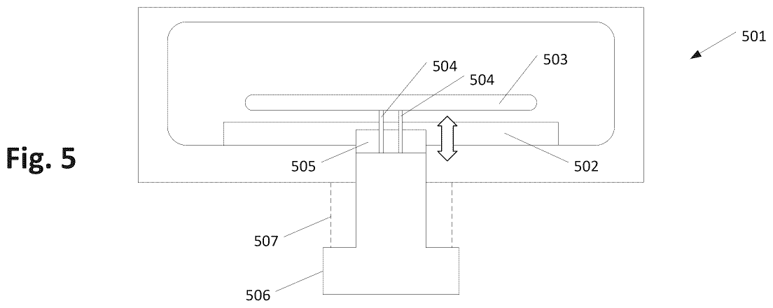

FIG. 5 shows an elevation view of a heater/cooling plate modifying the temperature of a wafer. FIG. 5 shows a load-lock module 501 configured to heat/cool wafers. The load-lock module 501 includes a heater/cooling plate 502 configured to change the temperature of a wafer 503. Lifting pins 504 are shown relative to the wafer and are used to transport the wafer. A drop in the temperature at the center of the wafer may be due to the lifting pins 504 acting as a heat sink during the heating of the wafer. FIG. 5 also shows a susceptor 505 and a linear actuator 506 configured to raise and lower the wafer 503 via lifting pins 504. The linear actuator 506 may include bellows 507 surrounding a movable portion of the linear actuator 506.

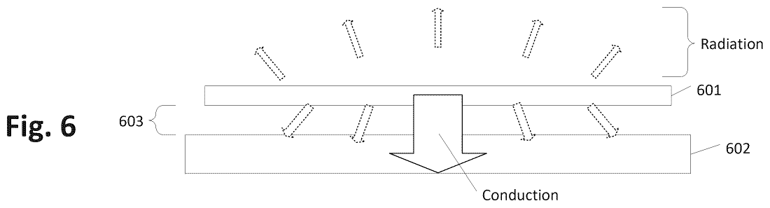

To help estimate how much the emissivities of regions are to be adjusted, heat transfer estimations are shown in FIG. 6. FIG. 6 is described in relation to the cooling of a wafer to better understand the influence of convection, conduction, and radiation on heat transfer. FIG. 6 shows an illustrative diagram of temperature transfer for a wafer 601 and temperature-adjusting plate 602 separated by space 603. Conduction is the primary driver of temperature change. In general, a wafer cools faster where an air gap between the wafer and a cooling plate is small (e.g., 0.5 mm compared to 2.0 mm). Convection cooling of the wafer (eliminating conduction and radiation) is still slower. Radiation cooling of the wafer (eliminating convection and conduction) is the slowest way of cooling a wafer. In short, convection is the primary driver of temperature modification. For example, the heat transfer equation may be used to estimate the results:

$$\dot{Q} = σ A {T}^{4} \qquad Equation 1$$

Where \dot{Q} is the power radiated, A is the surface area of the black body, T is the temperature of the black body, and σ is the Stefan-Boltzmann constant. To find the total power P emitted, the emissivity ε is included as P=\dot{Q}ε. The wafer temperature may be considered to be uniform, the calculation method was a first explicit method, radiation and conduction were considered, a nitrogen gas layer thickness at 1 mm, the wafer size was 300 mm in diameter×1 mm in thickness, and the emissivity of the wafer set to be 0.1.

The following table provides a sample of various emissivities and is available from https://en.wikipedia.org/wiki/Emissivity:

TABLE 1

| Material | Emissivity |
|---|---|
| Aluminum foil | 0.03 |
| Aluminum, anodized | 0.9 |
| Aluminum, rough, oxidized | 0.2 |
| Aluminum, smooth, polished | 0.04 |
| Copper, oxidized | 0.87 |
| Copper, polished | 0.04 |
| Iron, polished | 0.06 |
| Nitrogen or Oxygen gas layer, pure | ~0 |
| Polytetrafluoroethylene (Teflon) | 0.85 |
| Silver, oxidized | 0.04 |
| Silver, polished | 0.02 |
| Transition metal disilicides (e.g. MoSi2 or WSi2) | 0.86-0.93 |
| Water, pure | 0.96 |

Notably, the emissivity of smooth, polished aluminum is 0.04, rough, oxidized aluminum is 0.2, and anodized aluminum is 0.9. Accordingly, the variation in emissivity of aluminum, based on how it is processed, is significant and provides options for how to process a heater plate, for example, with an aluminum surface.

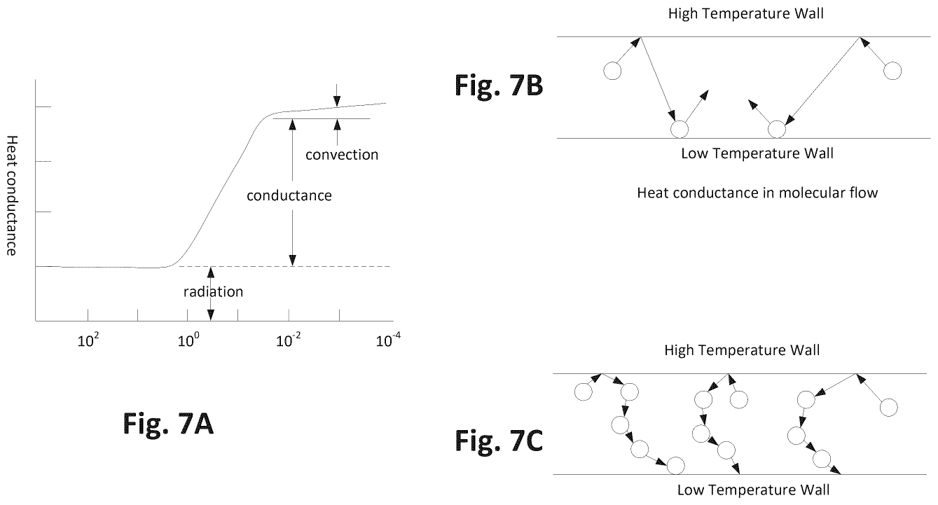

FIG. 7A is a graph showing heat conduction by radiation, conduction, and convection of a cooling plate. As shown in FIG. 7A, at lower pressures (e.g., greater distance between molecules shown on the left side of the graph), radiation is the primary heat transfer method. At higher pressures (e.g., shorter distances between molecules shown on the right side of the graph), conductance is the primary heat transfer method. In short, heat conductance is highly dependent on pressure. For instance, modeling molecular flow at low pressure results in a very low heat conductance (see FIG. 7B). Modeling viscous flow at high pressure results in a high heat conductance (see FIG. 7C). Here, the criteria of heat conduction is Kn<10⁻² (Kn=Knudsen number), at a pressure greater than 1350 Pa (10 Torr)/Gap=0.5 mm, is determined using the following Equation 2:

$$Kn = \frac{λ}{L} = \frac{\frac{{k}_{B} T}{\sqrt{2} {πσ}^{2} P}}{L} \qquad Equation 2$$

Where λ is the mean free path, which is the average distance that a moving particle collides with another to another; k_{B} is the Boltzmann constant; and L is the gap between the wafer and the cooling plate.

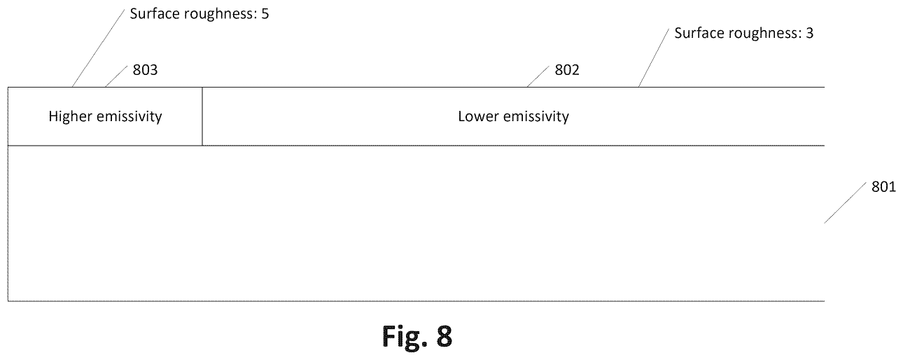

FIG. 8 shows an elevation view of a heater plate having variations in surface roughness. A heater plate 801 is shown with a lower emissivity region 802 having a surface roughness of 3 (a relative value) and a higher emissivity region 803 with a surface roughness of 5 (a relative value).

FIG. 9 shows a system with process modules, a substrate handling chamber, and a load lock. In various examples, one or more heater plates may be present one, two, or multiple of these structures. By having the heater plate in a given structure, the time consumed by downstream systems needing to subsequently heat a wafer to equalize the temperature across the wafer is reduced. FIG. 9 includes an equipment front-end module 902 with a robotic arm 903 having an end effector 904. The robotic arm 903 is configured to move semiconductor wafers between loading ports 901A, 901B, 901C, and 901D and a load-lock module 906. Load-lock module 906 includes one or more semiconductor holding locations 915 and/or 916 to temporarily support a semiconductor wafer while the atmosphere in the load-lock module 906 is being adjusted. Also, the one or more semiconductor holding locations 915 and/or 916 may include the heater plate described herein with the different emissivities to heat the wafer to a desired temperature. Similarly, the semiconductor wafer may be cooled at one or more of the semiconductor holding locations 915 and/or 916 by actively cooling the holding locations 915 or 916 or by allowing the wafers to cool as a temperature in the load-lock module 906 drops reduced or via a combination of these approaches.

The load-lock module 906 is connected at one edge or facet of a substrate handling chamber 919. The substrate handling chamber 919 may include or connect with a nitrogen gas source for providing a nitrogen gas atmosphere within the equipment front-end module 902. The equipment front-end module 902 receives new substrates for processing into the substrate processing system 900 and discharges processed substrates from the substrate processing system 900 via one or more loading ports 901A-901D (moving the substrates between the loading port(s) 901A-901D and the load-lock module 906 using the robotic arm 903). While four loading ports 901A-901D are shown in the example of FIG. 9, more or fewer loading ports may be provided in other examples of this technology.

The substrate handling chamber 919 is connected with multiple process modules 910. Wafers are transferred into the process modules 910 where one or more layers of material are deposited onto a surface of the substrate and/or other desired substrate processing takes place. FIG. 9 shows each process module 910 including four substrate supports 912 onto which substrates can be placed during processing. More or fewer substrate supports 912 may be provided in each process module 910 (e.g., the process modules 910 may be dual-chamber modules (DCM) or quad chamber modules (QCM)). Substrate processing chambers 910 in accordance with some examples of this technology may include another four substrate supports 912 located vertically beneath the four substrate supports 912 shown in the top view of FIG. 9. Each of the process modules 910 may have the same structures or one or more of the process modules 910 may have a different structure from other process modules 910 present. The substrate handling chamber 919 may also include one or more substrate supports 917/918 (two are shown in FIG. 9). The substrate supports may include a heater plate as described above. Further, one or more of the substrate supports 912 in the process chambers 910 may be a heater plate as described herein.

The substrate handling chamber 919 is connected with its respective process modules 910 via one or more gate valves 911. While two gate valves 911 are shown connecting substrate handling chamber 910 with process modules 910, more or fewer gate valves 911 may be provided for each process module 910. Substrate processing chambers 910 in accordance with some examples of this technology may be connected with the substrate handling chamber 919 by another two gate valves 911, e.g., located vertically beneath the two gate valves 911 shown in the top view of FIG. 9. When closed, the gate valves 911 sealingly separate the substrate handling chamber 919 the process modules 910 (so that independent atmospheric conditions may be maintained in each chamber). When open, the gate valves 911 provide an opening (e.g., a substrate transfer slot) through which the end effector 914 of a robotic arm 913 can extend to move substrates into and out of the process module 910. The openings through the gate valves 911 align with substrate transfer slots provided in the process modules 910 and the substrate handling chamber 919 to enable substrates to be moved between the process modules 910 and the substrate handling chamber 919 through the gate valves 911. Each of the gate valves 911 may have the same structures or one or more of the gate valves 911 may have a different structure from other gate valves 911 present.

One face 907 of the load-lock module 906 connects with the equipment front-end module 902 by one or more gate valves 905 (two are shown in FIG. 2), and the opposite face 908 of the load-lock module 906 connects with the substrate handling chamber 919 by one or more gate valves 909. The load-lock module 906 further includes one or more substrate supports 915/916 (two are shown in FIG. 9) for holding substrates while they wait to be moved into the equipment front-end module 902 or the substrate handling chamber 919. When closed, the gate valves 905, 909 sealingly separate the load-lock module 906 from the equipment front-end module 902 and the substrate handling chamber 919 (so that independent atmospheric conditions may be maintained in each chamber). When open, the gate valves 905 provide an opening (e.g., a substrate transfer slot) through which the end effector 904 of the robotic arm 903 can extend to move substrates into and out of the equipment front-end module 902. The openings through the gate valves 905 align with substrate transfer slots provided in the equipment front-end module 902 and the load-lock module 906 to enable substrates to be moved between the equipment front-end module 902 and the load-lock module 906 through gate valves 905. When open, the gate valves 909 provide an opening (e.g., a substrate transfer slot) through which the end effector 914 of robotic arm 913 can extend to move substrates into and out of the substrate handling chamber 919. The openings through the gate valves 909 align with substrate transfer slots provided in the substrate handling chamber 919 and the load-lock module 906 to enable substrates to be moved between the substrate handling chamber 919 and the load-lock module 906 through gate valves 909. Each of gate valves 905, 909 may have the same structure or one or more of the gate valves 905, 909 may have a different structure from other gate valves 905, 909.

Process modules 910 may include various equipment to perform semiconductor processing operations including but not limited to chemical vapor deposition, atomic layer deposition, lithography, etching, epitaxial growth, and other operations.

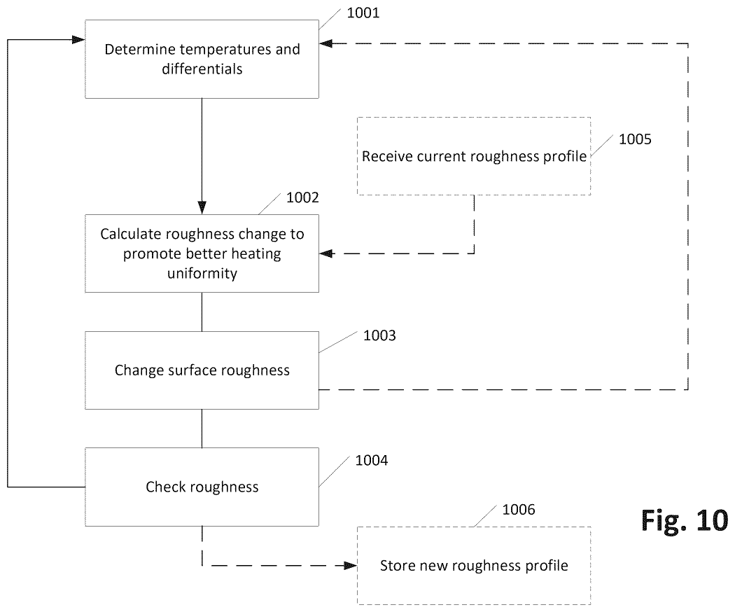

FIG. 10 shows a process for modifying the emissivity of one or more regions of a heater plate. In step 1001, temperatures are determined for various regions across a wafer. Differentials may also be determined between the measured regions. In step 1002, a system, using the emissivity for different roughnesses of a surface, calculates how much roughness change of a heater plate surface is needed to provide better heating uniformity (e.g., reducing the variation between regions of the wafer). In step 1003, the system modifies the surface roughness of one or more regions. The surface roughness may be modified by processes that increase the roughness of a surface, for instance, by blasting (e.g., by sand or another abrasive material), abrading (sanding, grinding, etc.), plating with different material or varying the color of a surface, painting, or anodizing. The degree of roughness or color modification may be minimal or significant or any degree in between to adjust the emissivity of a region. In step 1004, the surface roughness may be checked to ensure the desired roughness has been achieved and the temperatures measured for a wafer on the modified heater plate in step 1001. Alternatively, step 1004 may be skipped and temperatures measured again for a wafer in step 1001 using the modified heater plate.

Alternatively or additionally, in step 1005, a stored roughness profile of a heater plate may be obtained. The current roughness profile may be used to determine, in step 1002, how much modification of the roughness is needed for the heater plate. Also, following step 1004, a new roughness profile for the heater plate may be stored in step 1006 (and possibly subsequently used in step 1005, where further modifications of the roughness are desired).

In a first embodiment, a load-lock module comprises a first gate valve connectable to an equipment front-end module; a second gate valve connectable to a substrate handling chamber; and a heater plate. The heater plate comprises a surface having a center region with a center region emissivity and a peripheral region with a peripheral region emissivity and heating elements in a body of the heater plate. In the first example, the peripheral region emissivity is greater than the center region emissivity.

In one example, a roughness of the peripheral region is greater than a roughness of the center region. In another example, the peripheral region is darker in color than the center region. In yet another example, a transition between the peripheral region and the center region is defined by a large decrease in emissivity. Alternatively, the transition between the peripheral region and the center region is a gradient in roughness.

In a further example, the surface may include a third region between the center region and the peripheral region. An emissivity of the third region may be less than the peripheral region emissivity. The emissivity of the third region may be greater than the center region emissivity. The peripheral region emissivity may have been increased by blasting, abrading, plating, painting, or anodizing.

In a second embodiment, a cluster platform comprises a plurality of process modules and a load-lock module. The load-lock module comprises a first gate valve connectable to an equipment front-end module; a second gate valve connectable to a substrate handling chamber; and a heater plate. The heater plate comprises a surface having a center region with a center region emissivity and a peripheral region with a peripheral region emissivity, and heating elements in a body of the heater plate. The peripheral region emissivity is greater than the center region emissivity. The second embodiment further comprises a substrate handling chamber including a first robotic arm configured to move wafers between the process modules and the load-lock module.

In another example, the cluster platform may include a front-end module comprising a second robotic arm configured to move wafers between the load-lock module and one or more loading ports. A roughness of the peripheral region may be greater than a roughness of the center region. The peripheral region may be darker in color than the center region. The transition between the peripheral region and the center region may be defined by a large decrease in emissivity. Alternatively, the transition between the peripheral region and the center region may be a gradient in roughness. The surface may further comprise a third region between the center region and the peripheral region. The surface may include a third region between the center region and the peripheral region. An emissivity of the third region may be less than the peripheral region emissivity. The emissivity of the third region may be greater than the center region emissivity. The peripheral region emissivity may have been increased by blasting, abrading, plating, painting, or anodizing.

In a third embodiment, a process module comprises process equipment configured to perform a semiconductor-related process at an elevated temperature and a heater plate. The heater plate comprises a surface having a center region with a center region emissivity and a peripheral region with a peripheral region emissivity and heating elements in a body of the heater plate. The peripheral region emissivity is greater than the center region emissivity.

In further examples, roughness of the peripheral region may be greater than a roughness of the center region. The peripheral region may be darker in color than the center region. A transition between the peripheral region and the center region may be defined by a large decrease in emissivity. Alternatively, the transition between the peripheral region and the center region is a gradient in roughness.

Further, the surface of the heater plate of the process module may include a third region between the center region and the peripheral region. The third region may have an emissivity less than the peripheral region emissivity and greater than the center region emissivity.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A load-lock module comprising:
a first gate valve connectable to an equipment front-end module;
a second gate valve connectable to a substrate handling chamber; and
a heater plate comprising:
a surface having a center region with a center region emissivity and a peripheral region with a peripheral region emissivity; and
heating elements in a body of the heater plate,
wherein the peripheral region emissivity is greater than the center region emissivity.

2. The load-lock module of claim 1, wherein a roughness of the peripheral region is greater than a roughness of the center region.

3. The load-lock module of claim 1, wherein the peripheral region is darker in color than the center region.

4. The load-lock module of claim 1,
wherein a transition between the peripheral region and the center region is defined by a large decrease in emissivity.

5. The load-lock module of claim 1,
wherein a transition between the peripheral region and the center region is a gradient in roughness.

6. The load-lock module of claim 1, wherein the surface further comprises:
a third region between the center region and the peripheral region,
wherein the third region has a third region emissivity that is less than the peripheral region emissivity, and
wherein the third region emissivity is greater than the center region emissivity.

7. The load-lock module of claim 1, wherein the peripheral region emissivity was increased by:
blasting;
abrading;
plating;
painting; or
anodizing.

8. A cluster platform comprising:
a plurality of process modules;
a load-lock module comprising:
a first gate valve connectable to an equipment front-end module;
a second gate valve connectable to a substrate handling chamber; and
a heater plate comprising:
a surface having a center region with a center region emissivity and a peripheral region with a peripheral region emissivity; and
heating elements in a body of the heater plate, wherein the peripheral region emissivity is greater than the center region emissivity; and
a substrate handling chamber including a first robotic arm configured to move wafers between the process modules and the load-lock module.

9. The cluster platform of claim 8, further comprising:
a front-end module comprising a second robotic arm configured to move wafers between the load-lock module and one or more loading ports.

10. The cluster platform of claim 8,
wherein a roughness of the peripheral region is greater than a roughness of the center region.

11. The cluster platform of claim 8,
wherein the peripheral region is darker in color than the center region.

12. The cluster platform of claim 8,
wherein a transition between the peripheral region and the center region is defined by a large decrease in emissivity.

13. The cluster platform of claim 8,
wherein a transition between the peripheral region and the center region is a gradient in roughness.

14. The cluster platform of claim 8, wherein the surface further comprises:
a third region between the center region and the peripheral region,
wherein the third region has a third region emissivity that is less than the peripheral region emissivity, and
wherein the third region emissivity is greater than the center region emissivity.

15. The cluster platform of claim 8, wherein the peripheral region emissivity was increased by:
blasting;
abrading;
plating;
painting; or
anodizing.

16. A process module comprising:
process equipment configured to perform a semiconductor-related process at an elevated temperature; and
a heater plate comprising:
a surface having a center region with a center region emissivity and a peripheral region with a peripheral region emissivity; and
heating elements in a body of the heater plate,
wherein the peripheral region emissivity is greater than the center region emissivity.

17. The process module of claim 16,
wherein a roughness of the peripheral region is greater than a roughness of the center region.

18. The process module of claim 16,
wherein the peripheral region is darker in color than the center region.

19. The process module of claim 16, wherein the surface further comprises:
a third region between the center region and the peripheral region,
wherein the third region has a third region emissivity that is less than the peripheral region emissivity, and
wherein the third region emissivity is greater than the center region emissivity.

20. The process module of claim 16, wherein the peripheral region emissivity was increased by:
blasting;
abrading;
plating;
painting; or
anodizing.
